(19) United States
(12) Patent Application Publication
(10) Pub. No.: US 2012/0199829 A1
(43) Pub. Date: Aug. 9, 2012

(54) SEMICONDUCTOR DEVICE

(75) Inventor: Satoru Mayuzumi, Tokyo (JP)

(73) Assignee: SONY CORPORATION, Tokyo (JP)

(21) Appl. No.: 13/358,084

(22) Filed: Jan. 25, 2012

(30) Foreign Application Priority Data
Feb. 8, 2011 (JP) 2011-024568

(51) Int. Cl. H01L 23/544

(52) U.S. Cl. 257/48; 257/E23.179

(57) ABSTRACT

A semiconductor device includes: plural devices to be measured; and a combined array wiring including plural unit array wirings each having a column wiring and a row wiring provided in different layers as well as each connected to any one of the plural devices to be measured, in which the plural unit array wirings are provided in layers different from each other.

### FIELD

The present disclosure relates to a semiconductor device suitable for being used for an evaluation circuit of a semiconductor integrated circuit.

### BACKGROUND

In manufacture of a semiconductor integrated circuit, a test element group (TEG) is provided in a wafer for evaluating characteristics of devices included in a product. For example, there is disclosed a technique in which many transistors to be measured are arranged in a matrix state in the TEG and source terminals are arranged in common in JP-A-2008-140965 (Patent Document 1).

It is known that variations occur in size and characteristics of semiconductor devices such as a transistor and a resistor device according to the arrangement direction, and it is sometimes necessary to modify the arrangement direction of devices to be measured in the TEG for accurate measurement. Concerning such case, there is disclosed a technique in which the transistor to be measured can be rotated 90 degrees by combining L-shaped wirings to make a square layout in, for example, U.S. Pat. No. 7,489,151 (Patent Document 2).

### SUMMARY

However, one transistor to be measured is arranged in a square area surrounded by two wirings in a row direction and two wirings in a column direction in Patent Document 1, therefore, it is difficult to further improve arrangement density of wirings or transistors to be measured. Also in Patent Document 2, the square layout of wirings surrounding the transistor to be measured is redundant, which causes a problem that the arrangement density of transistors to be measured is reduced.

Thus, it is desirable to provide a semiconductor device capable of increasing arrangement density of devices to be measured.

An embodiment of the present disclosure is directed to a semiconductor device including plural devices to be measured and a combined array wiring including plural unit array wirings each having a column wiring and a row wiring provided in different layers as well as each connected to any one of the plural devices to be measured, in which the plural unit array wirings are provided in layers different from each other.

In the semiconductor device according to the embodiment of the present disclosure, plural unit array wirings each having the column wiring and the row wiring provided in different layers are provided in layers different from each other. Any one of the plural devices to be measured is connected to each unit array wiring. Therefore, it is possible to increase arrangement density of the devices to be measured by arranging plural unit array wirings so as to partially overlap each other.

Another embodiment of the present disclosure is directed to a semiconductor device including a combined array wiring including plural unit array wirings each having a column wiring and a row wiring provided in different layers, in which the plural unit array wirings are provided in layers different from each other and a device to be measured connected to any one of the plural unit array wirings.

In the semiconductor device according to the another embodiment of the present disclosure, plural unit array wirings each having the column wiring and the row wiring provided in different layers are provided in layers different from each other. The device to be measured is connected to any one of the plural unit array wirings. Therefore, it is possible to increase arrangement density of the devices to be measured by arranging plural unit array wirings so as to partially overlap each other.

According to the embodiments of the present disclosure, plural unit array wirings each having the column wiring and the row wiring provided in different layers are provided in layers different from each other, and any one of the plural devices to be measured is connected to each of the plural unit array wirings, as a result, arrangement density of the devices to be measured can be increased.

### BRIEF DESCRIPTION OF THE DRAWINGS

FIG. 1 is a plan view showing schematic positions of TEGs as semiconductor devices according to a first embodiment of the present disclosure on a wafer;

FIG. 2 is a plan view showing a configuration of a TEG shown in FIG. 1;

FIG. 3 is a cross-sectional view showing a configuration taken along line III-III of FIG. 2;

FIG. 4 is a cross-sectional view showing a configuration taken along line IV-IV of FIG. 2;

FIGS. 5A and 5B are views for explaining arrangement density of unit array wirings in the TEG shown in FIG. 2 in comparison with a related-art technique;

FIG. 6 is a plan view showing a configuration of a TEG according to a modification example 1-1;

FIG. 7 is a plan view showing a configuration of a TEG according to a modification example 1-2;

FIG. 8 is a plan view showing a configuration of a TEG according to a modification example 1-3;

FIG. 9 is a view showing a configuration of a TEG according to a modification example 1-4;

FIG. 10 is a cross-sectional view showing a configuration taken along line X-X of FIG. 9;

FIG. 11 is a cross-sectional view showing a configuration taken along line XI-XI of FIG. 9;

FIGS. 12A and 12B are views for explaining arrangement density of unit array wirings in the TEG shown in FIG. 9 in comparison with a related-art technique;

FIG. 13 is a view showing a configuration of a TEG according to a modification example 1-5;

FIG. 14 is a view showing a configuration of a TEG according to a modification example 1-6;

FIGS. 15A and 15B are views showing an example of connecting the unit array wiring and a transistor as a device to be measured when a TEG block according to a second embodiment of the present disclosure is arranged in the vertical direction, and FIGS. 15C and 15D are views showing an example of connecting the unit array wiring and the device to be measured when the TEG block shown in FIGS. 15A and 15B is arranged in the horizontal direction by rotating the TEG block 90 degrees to the left;

FIG. 16A is a view showing an example of connecting the wiring and the device to be measured in a related-art TEG, and FIG. 16B is a view showing an example of connecting the wiring and the device to be measured when the related-art TEG shown in FIG. 16A is arranged in the horizontal direction by rotating the TEG block 90 degrees to the left;

FIGS. 17A and 17B are views showing an example of connecting the unit array wiring and a resistor device as the device to be measured when a TEG block according to the modification example 2-1 is arranged in the vertical direction, and FIGS. 17C and 17D are views showing an example of connecting the unit array wiring and the device to be measured when the TEG block shown in FIGS. 17A and 17B is arranged in the horizontal direction by rotating the TEG block 90 degrees to the left;

FIG. 18 is a view showing a modification example of the TEG shown in FIG. 2; and

FIG. 19 is a view showing another modification example of the TEG shown in FIG. 2.

### DETAILED DESCRIPTION

Hereinafter, embodiments of the present disclosure will be explained in detail with reference to the drawings. The explanation will be made in the following order.

1. First Embodiment (Example in which two unit array wirings are included and devices to be measured are transistors)

2. Modification Example 1-1 (Example in which an orientation of a device to be measured is different)

3. Modification Example 1-2 (Example in which two unit array wirings are included and devices to be measured are resistor devices)

4. Modification Example 1-3 (Example in which an orientation of a device to be measured is different)

5. Modification Example 1-4 (Example in which three unit array wirings are included and devices to be measured are transistors)

6. Modification Example 1-5 (Example in which an orientation of a device to be measured is different)

7. Modification Example 1-6 (Example in which devices to be measured is a transistor, a resistor device and a capacitor)

8. Second Embodiment (Rotation of the TEG block; Example in which the device to be measured is a transistor)

9. Modification Example 2-1 (Rotation of the TEG block; Example in which the device to be measured is a resistor device)

### First Embodiment

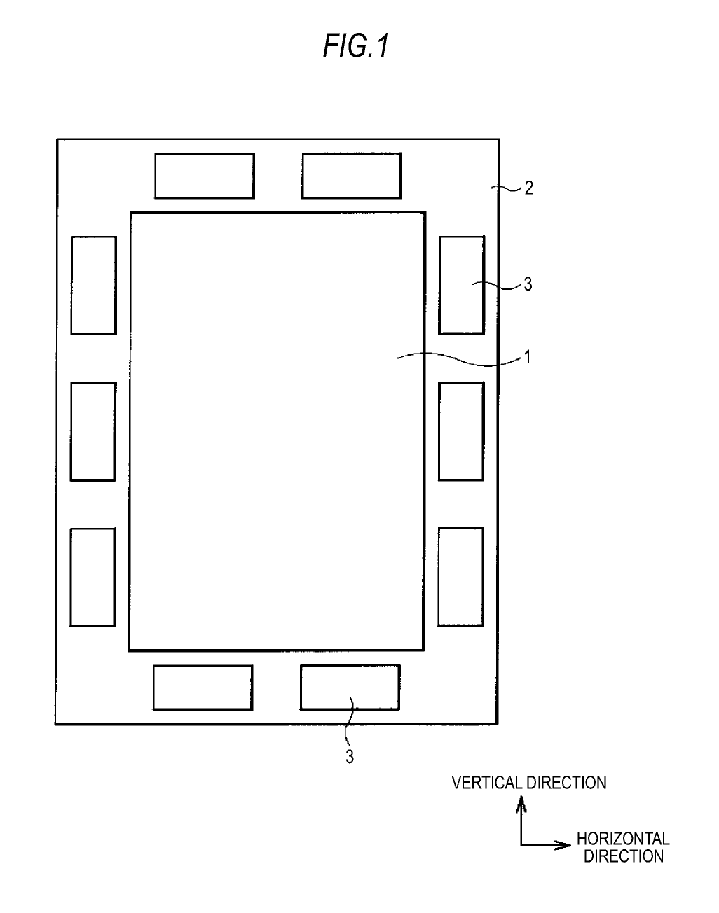

FIG. 1 shows schematic positions of TEGs as semiconductor devices according to a first embodiment of the present disclosure on a wafer. A product block 1 is arranged on the wafer (not shown) as an area where a semiconductor integrated circuit is formed. Though it goes without saying that plural product blocks 1 can be provided, only one product block 1 is shown in FIG. 1. A scribe line 2 for separating each product block 1 by cutting the wafer is provided around the product block 1 in a frame shape of in a grid shape. TEG blocks 3 are provided inside the scribe line 2. The TEG block 3 is an area where an evaluation circuit for evaluating characteristics of devices in a semiconductor integrated circuit in the product block 1 is provided. The TEG block 3 is arranged in the vertical direction (in portrait) inside the scribe line 2 along a vertical edge (for example, long edge) of the product block 1, and arranged in the horizontal direction (in landscape) inside the scribe line 2 along a horizontal edge (for example, short edge) of the product block 1. The arrangement of internal wirings is the same in the TEG block 3 in the vertical direction and in the TEG block 3 in the horizontal direction, and the arrangement direction merely differs (the arrangement is rotated 90 degrees to the right or left).

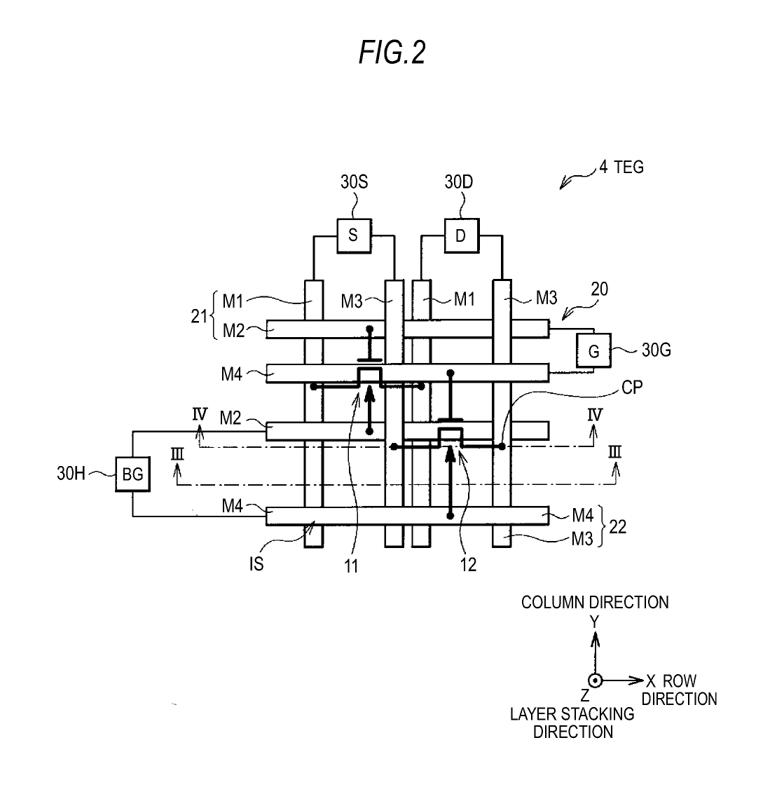

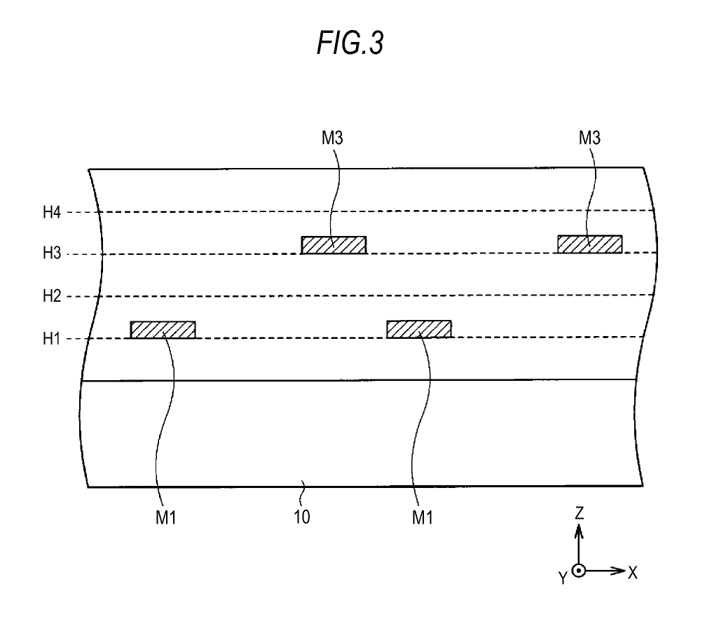

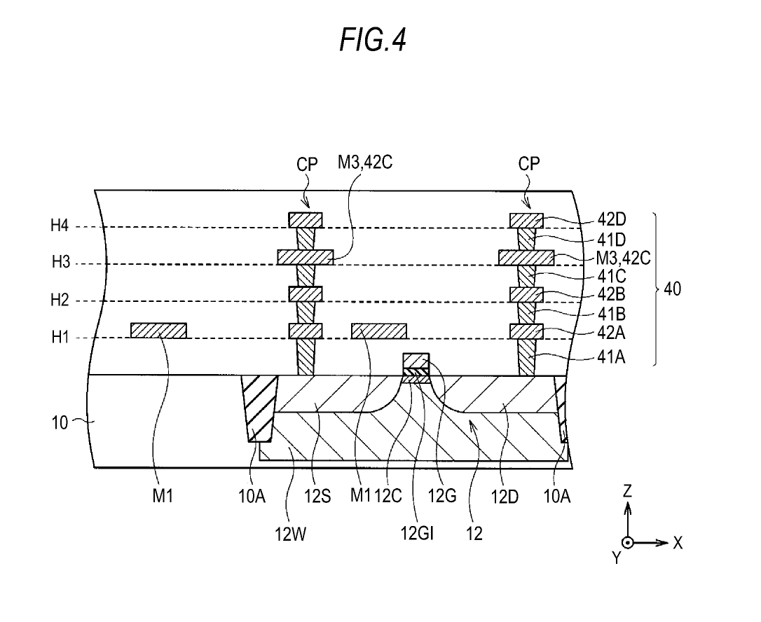

FIG. 2 shows a planar configuration of a TEG 4 provided in the TEG block 3 shown in FIG. 1. FIG. 3 shows a cross-sectional configuration taken along line III-III of FIG. 2 and FIG. 4 shows a cross-sectional configuration taken along IV-IV line of FIG. 2.

In the drawings after FIG. 2, a row direction is represented as an x-direction, a column direction is represented as a y-direction and a direction orthogonal (vertical) to the row direction and the column direction is represented as a z-direction. These x, y and z directions are directions in the TEG block 3. That is, the row-direction (x-direction) is the horizontal direction in the TEG block 3 laid out in the vertical direction shown in FIG. 1 and is the vertical direction in the TEG block 3 laid out in the horizontal direction. The column direction (y-direction) is the vertical direction in the TEG block 3 laid out in the vertical direction shown in FIG. 1 and is the horizontal direction in the TEG block 3 laid out in the horizontal direction. In FIG. 3 and FIG. 4, the first layer, the second layer, the third layer and the fourth layer corresponding to heights of wiring layers from the side of a substrate 10 are represented by dotted lines H1, H2, H3 and H4 respectively.

The TEG 4 includes plural (for example, two in FIG. 2) devices to be measured 11 and 12. The devices to be measured 11 and 12 are, for example, 4-terminal FETs (field-effect transistors) which are disposed in the same orientation. The device to be measured 11 is connected to a unit array wiring 21 including a column wiring M1 and a row wiring M2, and the device to be measured 12 is connected to a unit array wiring 22 including a column wiring M3 and a row wiring M4. The unit array wirings 21 and 22 form a combined array wiring 20.

The devices to be measured 11 and 12 are, for example, MOS-FETs provided on the substrate 10 as shown in FIG. 4. Though only the device to be measured 12 is shown in FIG. 4, the device to be measured 11 has the same configuration as the device to be measured 12. Specifically, the device to be measured 12 includes a gate insulating film 12GI and a gate electrode 12G as well as a channel region 12C in the substrate 10 just under the gate electrode 12G. At both sides of the channel region 12C, a diffusion layer (a source 12S and a drain 12D) is provided. The periphery of the device to be measured 12 is surrounded by a device isolation layer 10A and insulated from another device to be measured 11.

Connection portions 40 are provided at connection points CP between the devices to be measured 11, 12 and the unit array wirings 21, 22, for example, as shown in FIG. 4. Each connection portion 40 has a configuration in which vias 41A, 41B, 41C and 41D and metal layers 42A, 42B, 42C and 42D are stacked alternately on the source, the drain, a well (back gate) or a gate of each of the device to be measured 11 and 12. A bottom of the via 41A touches the source, the drain, the well (back gate) or the gate of the devices to be measured 11 and 12. The metal layer 42A has the same height H1 as the column wiring M1, the metal layer 42B has the same height H2 as the row wiring M2, the metal layer 42C has the same height H3 as the column wiring M3 and the metal layer 42D has the same height H4 as the row wiring M4. In each connection portion 40, only one of the column wirings M1, M3 and the row wirings M2, M4 is connected to only one of the metal layers 42A to 42D. For example, as shown in FIG. 4, the column wiring M3 is connected to the metal layer 42C of the connection portions 40 over the source 12S and the drain 12D of the device to be measured 12. Though not shown in FIG. 4, the connection portion 40 is provided also over the gate 12G of the device to be measured 12, and the row wiring M4 is connected to the metal layer 42D of the connection portion 40 over the gate 12G. Additionally, the connection portion 40 is provided also over the well (back gate) 12W of the device to be measured 12, and the row wiring M4 is connected to the metal layer 42D of the connection portion 40 over the well (back gate) 12W. The same applies to the device to be measured 11, though not shown.

It is preferable that the connection portions 40 are provided so as to avoid intersection positions IS between the column wirings M1, M3 and the row wirings M2, M4 in an xy-plane. When the connection portions 40 are provided at the intersection positions IS, the column wirings M1, M3 and the row wirings M2, M4 are all short-circuited through the connection portions 40 in the intersection positions IS.

The unit array wiring 21 includes the column wiring M1 in the y-direction and the row wiring M2 in the x-direction, and the unit array wiring 22 includes the column wiring M3 in the y-direction and the row wiring M4 in the x-direction. The column wiring M1 and the row wiring M2 are provided in different layers in the z-direction (for example, in the first layer H1 and the second layer H2 from the side of the substrate 10), and the column wiring M3 and the row wiring M4 are provided in different layers in the z -direction (for example, in the third layer H3 and the fourth layer H4 from the side of the substrate 10). Furthermore, the unit array wirings 21 and 22 are provided in layers different from each other in the z-direction (for example, the first layer H1 and the second layer H2, the third layer H3 and the fourth layer H4 from the side of the substrate 10). Accordingly, it is possible to increase arrangement density of the devices to be measured 11 and 12 in the TEG 4.

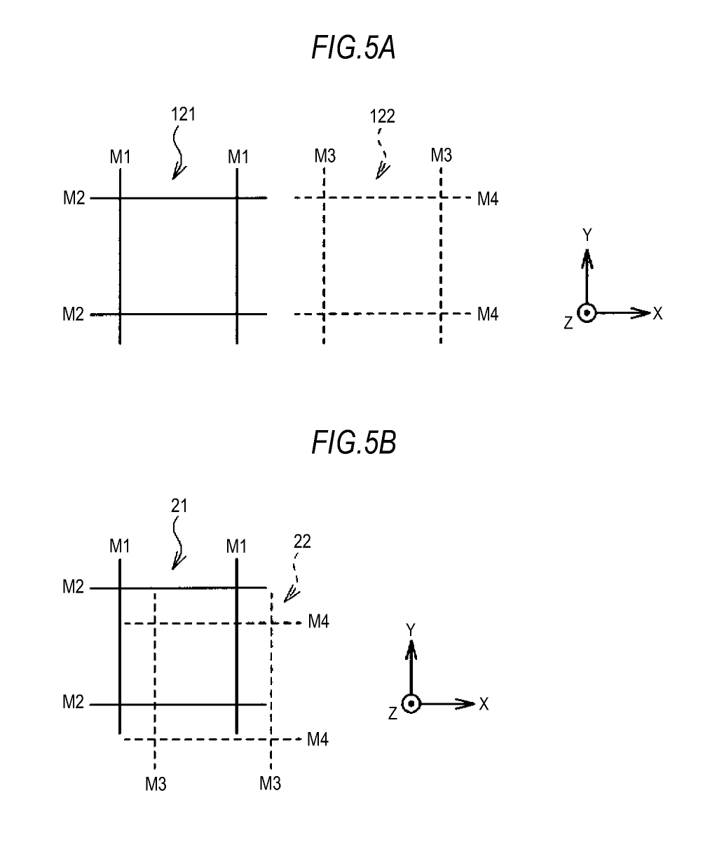

That is, it is difficult to arrange devices to be measured (not shown) in high density in related art techniques because integration is performed by arranging square wiring layouts 121 and 122 including column wirings M1, M3 and the row wirings M2 and M4 surrounding the devices to be measured in the xy-plane in parallel or in the same layer in the z -direction as shown in FIG. 5A. In response to this, the unit array wirings 21 and 22 are arranged so as to partially overlap each other in the present embodiment as shown in FIG. 5B, therefore, many devices to be measured can be provided in the same area as long as wiring density permits. Accordingly, it is possible to arrange the devices to be measured 11 and 12 in high density.

It is preferable that the column wirings M1 and the column wirings M3 are respectively arranged at positions displaced to each other in the x-direction (positions where they do not overlap each other) in the xy-plane (a plane parallel to the paper in FIG. 2) including the x-direction and the y-direction. Similarly, it is preferable that the row wirings M2 and the row wirings M4 are arranged at positions displaced to each other in the y-direction (positions where they do not overlap each other) in the xy-plane. In other words, it is preferable that the column wirings M1, M3 and the row wirings M2, M4 do not intersect at a point. Accordingly, the column wirings M1, M3 and the row wirings M2, M4 make a grid in which they do not overlap each other in the xy-plane. As described above, the connection portions 40 are provided at the connection points CP between the unit array wirings 21, 22 and the devices to be measured 11, 12, and each connection portion 40 has a configuration in which the column wirings M1, M3 and the row wirings M2, M4 are short circuited through respective vias 41A to 41D. Therefore, when applying the grid layout as described above, it is possible to suppress short circuit between the column wirings M1 and M3, short circuit between the row wirings M2 and M4, short circuit between the column wirings M1, M3 and the row wirings M2, M4 when the unit array wirings 21, 22 are connected to devices to be measured 11, 12.

The unit array wiring 21 includes two column wirings M1 in the same layer (for example, the first layer from the side of the substrate 10) and two row wirings M2 in the same layer (for example, the second layer from the side of the substrate 10). The unit array wiring 22 includes two column wirings M3 in the same layer (for example, the third layer from the side of the substrate 10) and two row wirings M4 in the same layer (for example, the fourth layer from the side of the substrate 10). The source and the drain of the device to be measured 11 are connected to the column wiring M1. The gate and the back gate of the device to be measured 11 are connected to the row wiring M2. The source and the drain of the device to be measured 12 are connected to the column wiring M3. The gate and the back gate of the device to be measured 12 are connected to the row wiring M4.

Wirings in the column wirings M1, M3 and the row wirings M2, M4 to be connected to the same portions of the devices to be measured 11 and 12 are connected in common to a measurement pad. That is, the column wiring M1 to which the source of the device to be measured 11 is connected and the column wring M3 to which the source of the device to be measured 12 is connected are connected in common to a source pad 30S. The column wring M1 to which the drain of the device to be measured 11 is connected and the column wiring M3 to which the drain of the device to be measured 12 is connected are connected in common to a drain pad 30D. The row wiring M2 to which the gate of the device to be measured 11 is connected and the row wiring M4 to which the gate of the device to be measured 12 is connected are connected in common to a gate pad 30G. The row wiring M2 to which the back gate of the device to be measured 11 is connected and the row wiring M4 to which the back gate of the device to be measured 12 is connected are connected in common to a back gate pad 30H.

The number of column wirings M1, M3 or the row wirings M2, M4 can be increased/decreased in accordance with the configuration and the like of the devices to be measured 11 and 12 to be connected. For example, it is also preferable that the unit array wiring 21 includes two column wirings M1 in the first layer, one row wiring M2 in the second layer and one row wiring in the third layer. However, in such case, connection to the device to be measured will be more complicated in the case where many unit array wirings are provided. Therefore, it is preferable that one unit array wiring 21 (or 22) includes two column wirings M1 (or M3) in the first layer and includes two row wirings M2 (or M4) in the second layer. In the case where the device to be measured 11 is a FET, a passive device, an active device or the like which can be configured by three terminals, the unit array wiring 21 (or 22) may include two column wirings M1 (or M3) in the first layer and includes one row wiring M2 (M4) in the second layer.

In the TEG 4, the unit array 21 including the column wirings M1 and the row wirings M2 provided in different layers and the unit array wiring 22 including the column wirings M3 and the row wirings M4 provided in different layers are provided in different layers. Any one of plural devices to be measured 11 and 12 is connected to each of the unit array wirings 21 and 22 respectively. Therefore, plural unit array wirings 21 and 22 are arranged so as to partially overlap each other, thereby increasing the arrangement density of the devices to be measured 11 and 12. It is also possible to arrange the devices to be measured 11 and 12 closely, as a result, pair characteristics (local variation) of two devices to be measured 11 and 12 can be accurately evaluated.

Accordingly, the unit array wiring 21 including the column wirings M1 and the row wirings M2 provided in different layers and the unit array wiring 22 including the column wirings M3 and the row wirings M4 provided in different layers are provided in different layers, and any one of plural devices to be measured 11 and 12 is connected to each of the plural unit array wirings 21 and 22 respectively in the embodiment, therefore, the arrangement density of the devices to be measured 11 and 12 can be increased. Accordingly, it is possible to increase the degree of location of the devices to be measured 11 and 12 as well as to acquire evaluation information of various devices. The TEG 4 is remarkably reduced in size along with miniaturization of an LSI (Large Scale Integrated Circuit), and the device according to the embodiment can respond to the integration of the devices to be measured with high density for following the miniaturization.

It is also possible to arrange the devices to be measured 11 and 12 closely, therefore, pair characteristics (local variation) of two devices to be measured 11 and 12 can be accurately evaluated. Particularly, a circuit configuration in which characteristics of closely-arranged devices are utilized is often used in analog semiconductors, and the TEG 4 according to the embodiment is extremely suitable for an evaluation circuit of such analog semiconductor circuits.

### MODIFICATION EXAMPLE 1-1

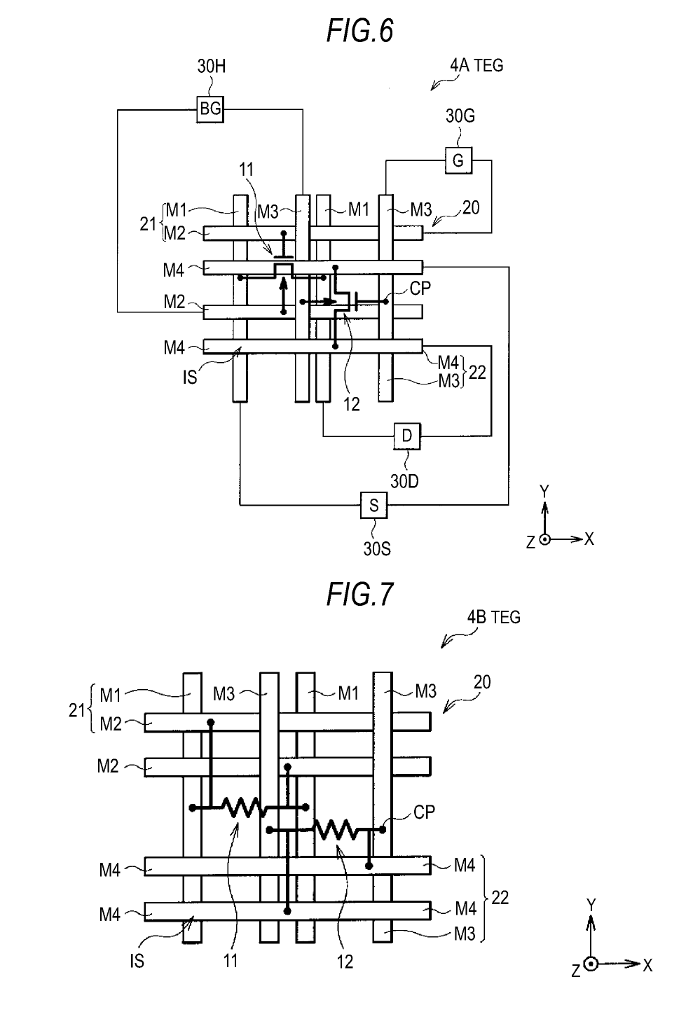

FIG. 6 shows a configuration of a TEG 4A according to a modification example 1-1. In the present modification example, an orientation of one of the devices to be measured which is numbered 12 differs from the TEG 4 of the first embodiment shown in FIG. 2. The TEG 4A of the present modification example has the same configuration, operations and effects as the first embodiment. It is known that variations occur in size and characteristics of semiconductor devices such as the transistor or the resistor device according to the arrangement direction, however, variations in characteristics and the like according to the arrangement direction (an orientation of the gate) of the devices to be measured 11 and 12 can be particularly evaluated.

Specifically, the gate and the back gate of the device to be measured 12 are connected to the column wiring M3. The source and the drain of the device to be measured 12 are connected to the row wiring M4.

Also in the present modification example, wirings in the column wrings M1, M3 and the row wirings M2, M4 to be connected to the same portions of the devices to be measured 11 and 12 are connected in common to the measurement pad in the same manner as the first embodiment. However, in the present modification example, the combination of connection between the column wrings M1, M3 as well as the row wirings M2, M4 and the measurement pads is changed according to the change of the arrangement direction of the device to be measured 12. That is, the column wiring M1 to which the source of the device to be measured 11 is connected and the row wiring M4 to which the source of the device to be measured 12 is connected are connected in common to the source pad 30S. The column wiring M1 to which the drain of the device to be measured 11 is connected and the row wiring M4 to which the drain of the device to be measured 12 is connected are connected in common to the drain pad 30D. The row wiring M2 to which the gate of the device to be measured 11 is connected and the column wiring M3 to which the gate of the device to be measured 12 is connected are connected in common to the gate pad 30G. The row wiring M2 to which the back gate of the device to be measured 11 is connected and the column wiring M3 to which the back gate of the device to be measured 12 is connected are connected in common to the back gate pad 30H.

### MODIFICATION EXAMPLE 1-2

FIG. 7 shows a configuration of a TEG 4B according to a modification example 1-2. The present modification example has the same configuration, operations and effects as the first embodiment except that the devices to be measured 11 and 12 are resistor devices. In the present modification example, characteristics of the resistor devices can be measured by using a 4-terminal method. It is also possible to evaluate pair characteristics by close arrangement in the same manner as the first embodiment.

### MODIFICATION EXAMPLE 1-3

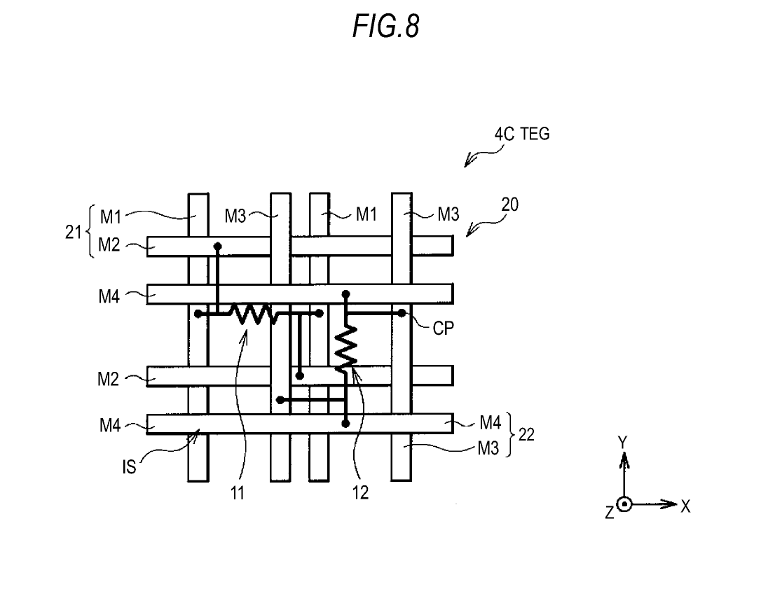

FIG. 8 shows a configuration of a TEG 4C according to a modification example 1-3. The present modification example has the same configuration, operations and effects as the first embodiment except that an orientation of one of the devices to be measured which is numbered 12 is different from the TEG 4B of the modification example 1-2 shown in FIG. 7. In the present modification example, variations in characteristics and the like depending of the arrangement direction of the devices to be measured 11 and 12 can be evaluated.

### MODIFICATION EXAMPLE 1-4

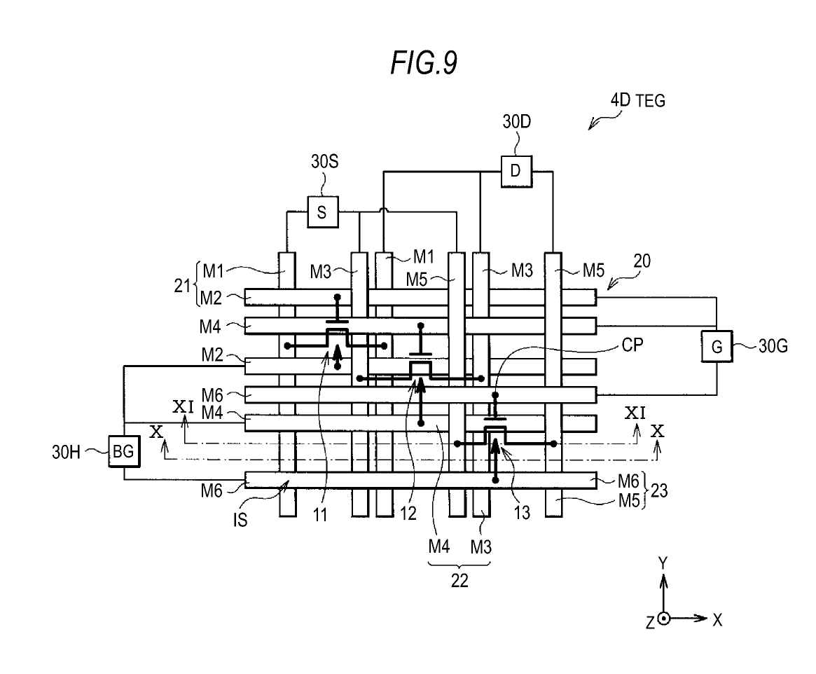

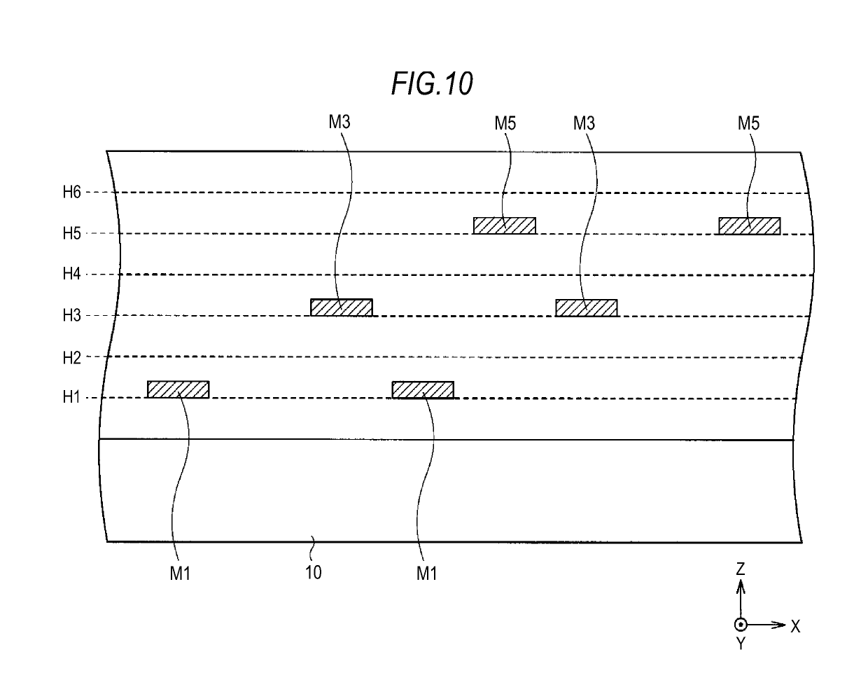

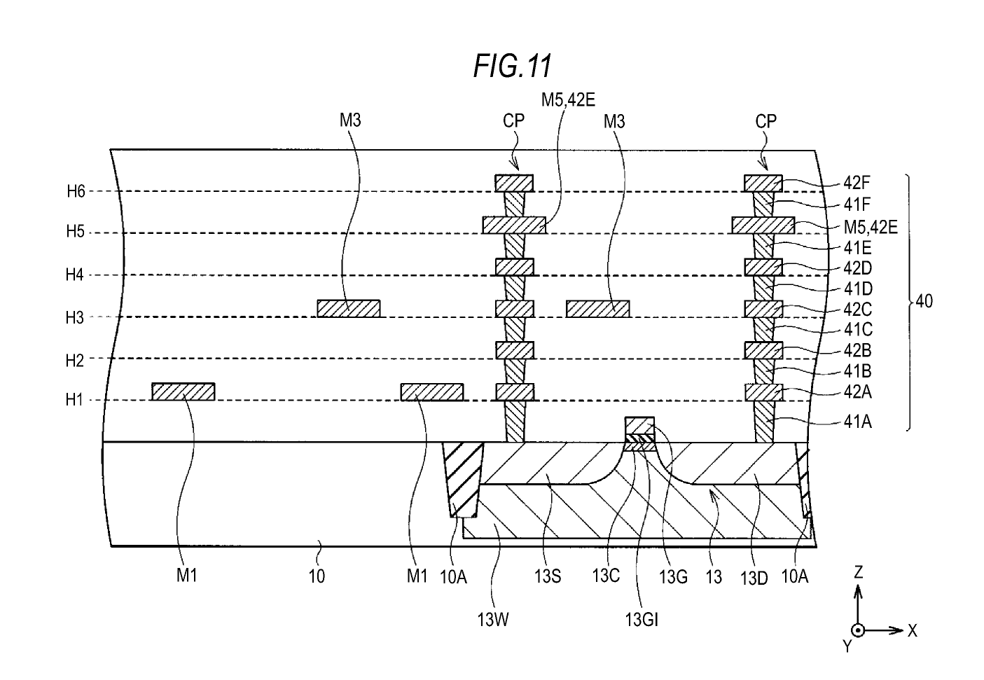

FIG. 9 shows a configuration of a TEG 4D according to a modification example 1-4. FIG. 10 is a cross-sectional configuration taken along X-X line of FIG. 9 and FIG. 11 shows a cross-configuration taken along XI-XI line of FIG. 9. In FIG. 10 and FIG. 11, the first layer, the second layer, the third layer, the four layer, the fifth layer and the sixth layer corresponding to the heights of wiring layers from the side of the substrate 10 are represented by dotted lines H1, H2, H3, H4, H5 and H6 respectively.

In the present modification example, three devices to be measured 11, 12 and 13 are respectively connected to unit array wirings 21, 22 and 23. The unit arrays wirings 21, 22 and 23 form the combined array wiring 20. The TEG 4D of the present modification example has the same configuration, operations and effects as the first embodiment except the above.

All the devices to be measured 11 to 13 are 4-termianal FETs similar to the first embodiment, which are arranged in the same orientation.

At the connection points CP between the devices to be measured 11 to 13 and the unit array wirings 21 to 23, the connection portions 40 as shown, for example, in FIG. 11 are provided. Each connection portion 40 has a configuration in which vias 41A, 41B, 41C, 41D, 41E and 41F and metal layers 42A, 42B, 42C, 42D, 42E and 42F are stacked alternately on the source, the drain, or the gate of each of the device to be measured 11 to 13. A bottom of the via 41A touches the source, the drain, or the gate of the devices to be measured 11 to 13. The metal layer 42A has the same height H1 as the column wiring M1, the metal layer 42B has the same height H2 as the row wiring M2, the metal layer 42C has the same height H3 as the column wiring M3, the metal layer 42D has the same height H4 as the row wiring M4, the metal layer 42E has the same height H5 as the column wiring M5 and the metal wiring 42F has the same height H6 as the row wiring M6. In each connection portion 40, only one of the column wirings M1, M3, M5 and the row wirings M2, M4, M6 is connected to only one of the metal layers 42A to 42F. For example, as shown in FIG. 11, the column wiring M5 is connected to the metal layer 42E of the connection portions 40 over the source 13S and the drain 13D of the device to be measured 13. Though not shown in FIG. 11, the connection portion 40 is provided also over a gate of the device to be measured 13, and the row wiring M6 is connected to the metal layer 42F of the connection portion 40 over the gate. Additionally, the connection portion 40 is provided also over the well (back gate) 13W of the device to be measured 13, and the row wiring M6 is connected to the metal layer 42F of the connection portion 40 over the well (back gate) 13W. The same applies to the devices to be measured 11 and 12 though not shown.

It is preferable that the connection portions 40 are provided so as to avoid intersection positions IS between the column wirings M1, M3, M5 and the row wirings M2, M4, M6 in the xy-plane. When the connection portions 40 are provided at the intersection positions IS, the column wirings M1, M3, M5 and the row wirings M2, M4, M6 are all short-circuited through the connection portions 40 in the intersection positions IS.

The unit array wirings 21 and 22 have the same configuration as the first embodiment. The unit array wiring 23 includes the column wiring M5 in the y-direction and the row wiring M6 in the x-direction. The column wiring M5 and the row wiring M6 are provided in different layers in the z-direction (for example, in the fifth layer H5 and the sixth layer H6 from the side of the substrate 10). Furthermore, the unit array wirings 21 to 23 are provided in layers different from one another in the z-direction (for example, the first layer H1 and the second layer H2, the third layer H3 and the fourth layer H4, the fifth layer H5 and the sixth layer H6 from the side of the substrate 10). Accordingly, it is possible to increase arrangement density of the devices to be measured 11 to 13.

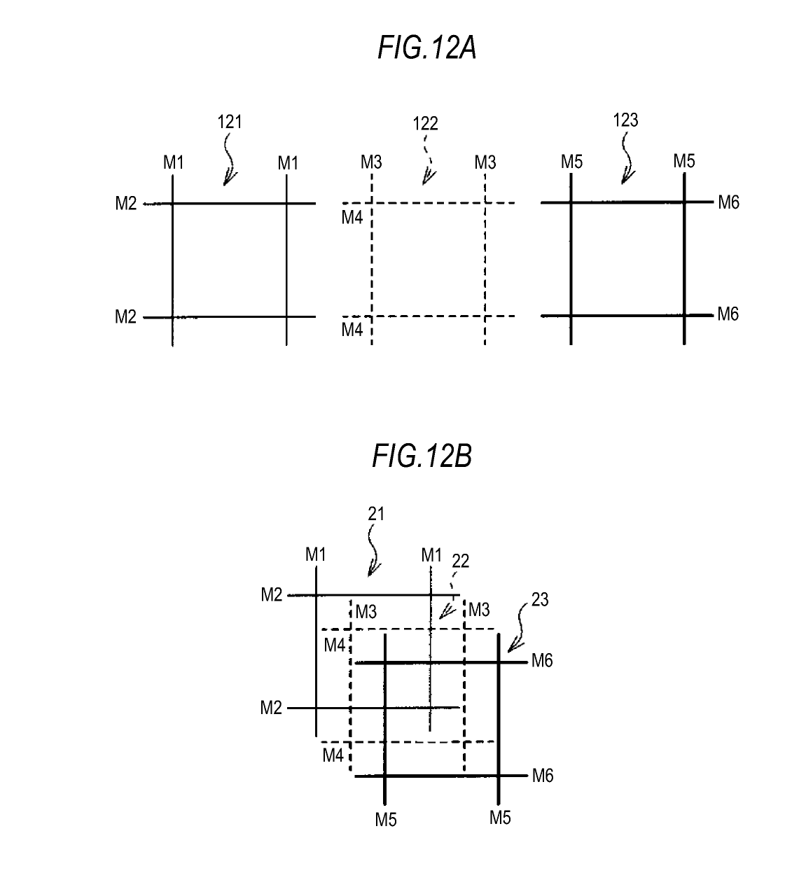

That is, it is difficult to arrange devices to be measured (not shown) in high density in related art techniques because square wiring layouts 121, 122 and 123 including column wirings M1, M3, and M5 and the row wirings M2, M4 and M6 surrounding the devices to be measured in the xy-plane in parallel or in the same layer in the z-direction as shown in FIG. 12A. In response to this, the unit array wirings 21, 22 and 23 are arranged so as to partially overlap one another in the present embodiment as shown in FIG. 12B, therefore, many devices to be measured can be provided in the same area as long as wiring density permits. Accordingly, it is possible to arrange the devices to be measured 11 to 13 in high density.

It is preferable that the column wirings M1, M3 and M5 are respectively arranged at positions displaced to one another in the x-direction (positions where they do not overlap each other) in the xy-plane. Similarly, it is preferable that the row wiring M2, M4 and M6 are arranged at positions displaced to one another in the y-direction (positions where they do not overlap one another). In other words, it is preferable that the column wirings M1, M3 and M5 and the row wirings M2, M4 and M6 do not intersect at a point. Accordingly, the column wirings M1, M3, M5 and the row wirings M2, M4, M6 make a grid in which they do not overlap one another in the xy-plane. As described above, the connection portion 40 is provided at each of the connection points CP between the unit array wirings 21 to 23 and the devices to be measured 11 to 13 and the connection portion 40 has a configuration in which the column wirings M1, M3 and M5 as well as the row wirings M2, M4 and M6 are short circuited through respective vias 41A to 41F. Therefore, when applying the grid layout as described above, it is possible to suppress short circuit among the column wirings M1, M3 and M5, short circuit among the row wirings M2, M4 and M6, short circuit between the column wirings M1, M3, M5 and the row wirings M2, M4, M6 when the unit array wirings 21 to 23 are connected to devices to be measured 11 to 13.

The unit array wiring 23 includes two column wirings M5 in the same layer (for example, the fifth layer from the side of the substrate 10) and two row wirings M6 in the same layer (for example, the sixth layer from the side of the substrate 10). The source and the drain of the device to be measured 13 are connected to the column wiring M5. The gate and the back gate of the device to be measured 13 are connected to the row wiring M6.

Wirings in the column wrings M1, M3, M5 and the row wirings M2, M4, M6 to be connected to the same portions of the devices to be measured 11 to 13 are connected in common to the measurement pad. That is, the column wiring M1 to which the source of the device to be measured 11 is connected, the column wring M3 to which the source of the device to be measured 12 is connected and the column wiring M5 to which the source of the device to be measured 13 is connected are connected in common to the source pad 30S. The column wring M1 to which the drain of the device to be measured 11 is connected, the column wiring M3 to which the drain of the device to be measured 12 is connected and the column wiring M5 to which the drain of the device to be measured 13 is connected are connected in common to the drain pad 30D. The row wiring M2 to which the gate of the device to be measured 11 is connected, the row wiring M4 to which the gate of the device to be measured 12 is connected and the row wiring M6 to which the gate of the device to be measured 13 is connected are connected in common to the gate pad 30G. The row wiring M2 to which the back gate of the device to be measured 11 is connected, the row wiring M4 to which the back gate of the device to be measured 12 is connected and the row wiring M6 to which the back gate of the device to be measured 13 is connected are connected in common to the back gate pad 30H.

The number of column wirings M1, M3 and M5 or the row wirings M2, M4 and M6 can be increased/decreased in accordance with the configuration of the devices to be measured 11 to 13 in the same manner as the first embodiment. It is preferable that one unit array wiring 21 (or 22, 23) includes two column wirings M1 (or M3, M5) in the first layer and includes two row wirings M2 (or M4, M6) in the second layer. In the case where the device to be measured 11 to 13 are FETs, passive devices or active devices which can be configured by three terminals, the unit array wiring 21 (or 22, 23) may include two column wirings M1 (or M3, M5) in the first layer and includes one row wiring M2 (M4, M6) in the second layer.

In the TEG 4D, the unit array 21 including the column wirings M1 and the row wirings M2 provided in different layers, the unit array wiring 22 including the column wirings M3 and the row wirings M4 provided in different layers and the unit array wiring 23 including the column wirings M5 and the row wirings M6 provided in different layers are provided in layers different from one another. Any one of plural devices to be measured 11 to 13 is connected to each of the unit array wirings 21 to 23 respectively. Therefore, plural unit array wirings 21 to 23 are arranged so as to partially overlap one another, thereby increasing the arrangement density of the devices to be measured 11 to 13. It is also possible to arrange the devices to be measured 11 to 13 closely, as a result, pair characteristics (local variation) of devices to be measured 11 to 13 can be accurately evaluated.

Accordingly, the unit array wiring 21 including the column wirings M1 and the row wirings M2 provided in different layers, the unit array wiring 22 including the column wirings M3 and the row wirings M4 provided in different layers and the unit array 23 including the column wirings M5 and the row wirings M6 provided in different layers are provided in different layers, and any one of plural devices to be measured 11 to 13 is connected to each of the plural unit array wirings 21 to 23 respectively in the present modification example, therefore, the arrangement density of the devices to be measured 11 to 13 can be increased.

### MODIFICATION EXAMPLE 1-5

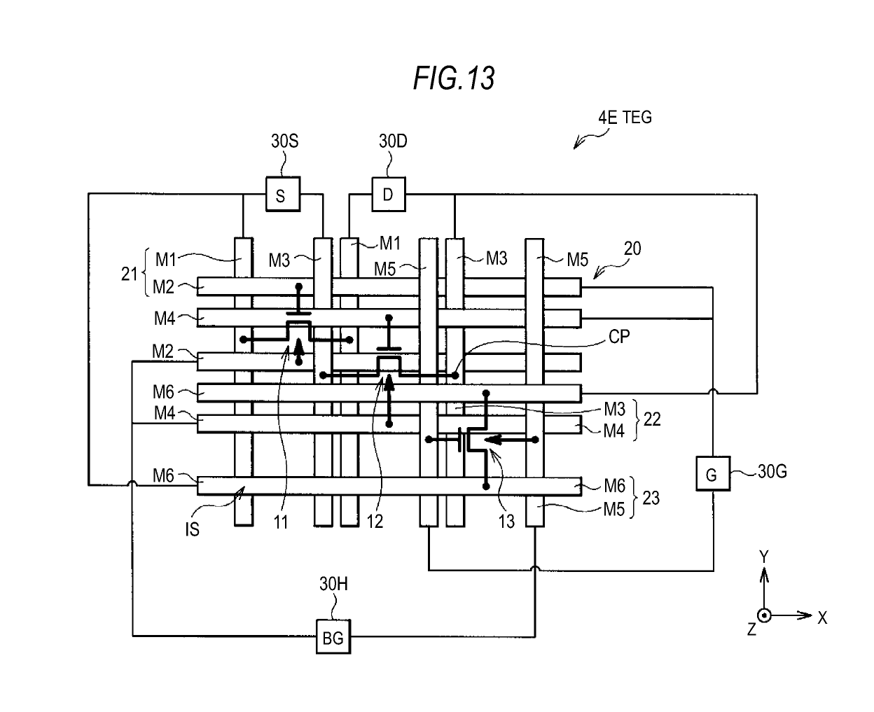

FIG. 13 shows a configuration of a TEG 4E according to a modification example 1-5. In the present modification example, an orientation of one device to be measured which is numbered 13 differs from the TEG 4D of the modification example 1-4 shown in FIG. 9. That is, the gate and the back gate of the device to be measured 13 are connected to the column wiring M5. The source and the drain of the device to be measured 13 are connected to the row wiring M6. In the modification example, variations in characteristics and the like according to the arrangement direction (the orientation of the gate) of the devices to be measured 11 to 13 can be particularly evaluated.

### MODIFICATION EXAMPLE 1-6

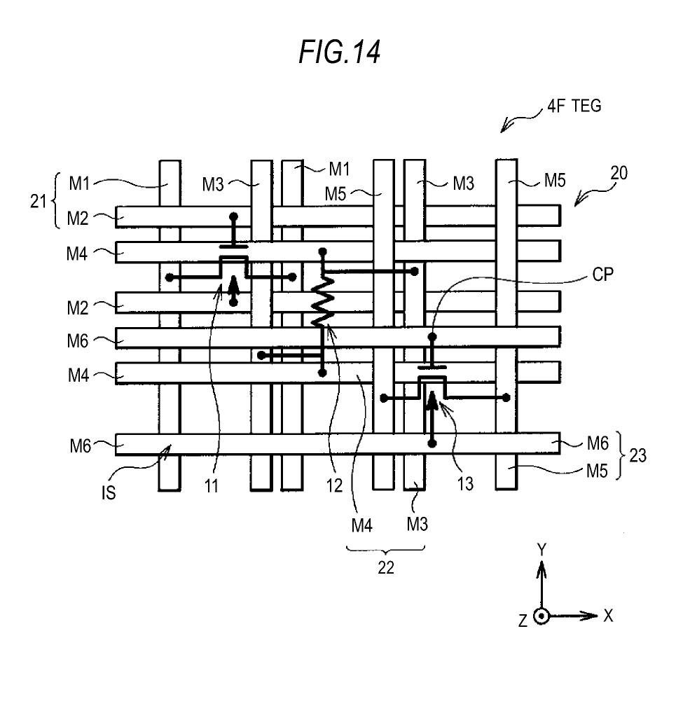

FIG. 14 shows a configuration of a TEG 4F according to a modification example 1-6. The present modification example has the same configuration, operations and effects as the first embodiment and the modification example 1-5 except that the device to be measured 11 is a transistor, the device to be measured 12 is a resistor device and the device to be measured 13 is a capacitor in the TEG 4D of the modification example 1-5 shown in FIG. 9.

In order to evaluate characteristics of one device in detail, it is necessary to separate components of resistance, capacitance and so on. For example, in order to separately evaluate characteristic parameters of one transistor, evaluation of various resistance or capacitance such as gate resistance or gate capacitance will be necessary. In the modification example, it is possible to arbitrarily combine the transistor, the resistor device, the capacitor and so on as the device to be measured 11 to 13, therefore, evaluation using the devices to be measured 11 to 13 which are closely arranged in high density is possible at the time of performing separate evaluation of characteristic parameters of a single device. Accordingly, variation components due to arrangement positions can be reduced and respective characteristic components can be evaluated accurately. Additionally, it is possible to analyze components to find faults of characteristics of, for example, the transistor by measuring neighboring devices.

A device configuration obtained by combining many novel materials and novel techniques is coming to be applied as a process generation makes progress. Accordingly, plural characteristic parameters included in the single device are important for evaluation of circuit characteristics and yield management. The modification example is suitable for evaluation of the devices adopted such novel materials and novel techniques.

In the present modification example, the case where the devices to be measured 11 to 13 are different types of devices respectively (the transistor, the resistor device and the capacitor) and respective devices can measure different characteristics (various characteristics of the transistor, resistance and capacitance) has been explained, however, it is also preferable that at least one of the devices to be measured 11 to 13 is a device which is different from other devices to be measured and can measure characteristics different from other device to be measured.

### Second Embodiment

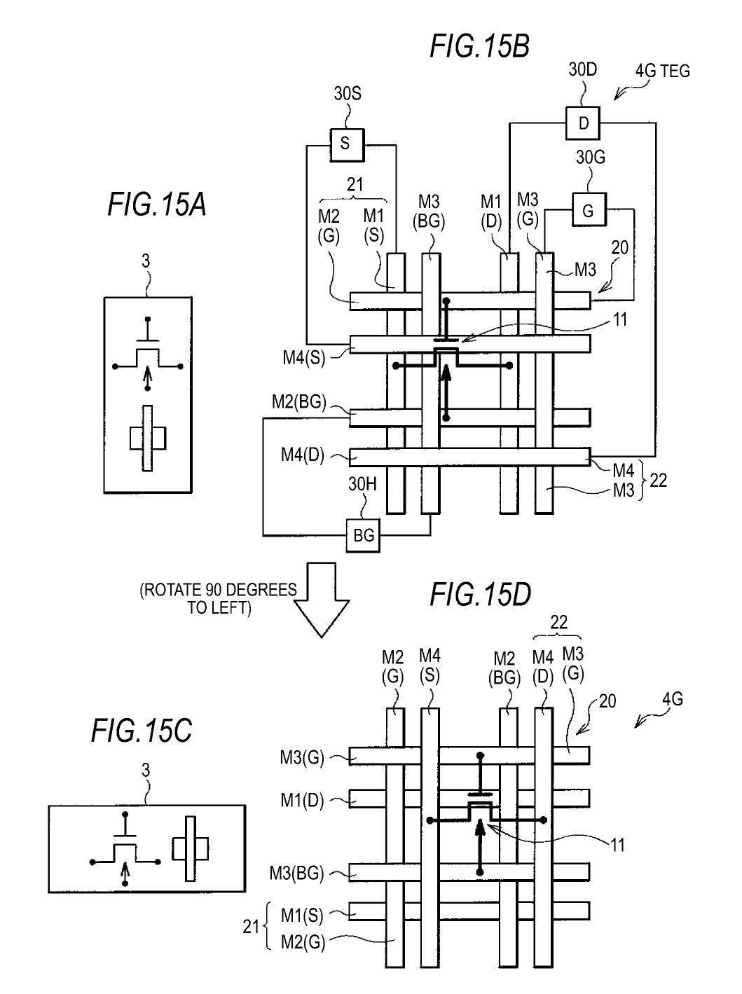

FIGS. 15A to 15D show a configuration of a TEG 4G according to a second embodiment of the present disclosure. In the second embodiment, the device to be measured 11 is connected to any one of the unit array wirings 21 and 22 according to the arrangement direction of the TEG block 3 shown in FIG. 1, thereby enabling changing the arrangement direction of the device to be measured 11. The present embodiment has the same configuration, operations and effects as the first embodiment except this point. Therefore, the same signs are given to corresponding components to make explanation.

As shown in FIG. 15A, when the TEG block 3 (refer to FIG. 1) is arranged in the vertical direction (in portrait), the column wirings M1 and M3 are in vertical direction and the row wirings M2 and M4 are in the horizontal direction in the TEG 4G as shown in FIG. 15B.

As shown in FIG. 15A, when the gate of the transistor is desired to be arranged in the vertical direction in the TEG block 3, the device to be measured 11 is connected to the unit array wiring 21 in the TEG 4G as shown in FIG. 15B. That is, the source and the drain of the device to be measured 11 are connected to the column wirings M1 and the gate and the back gate of the device to be measured 11 are connected to the row wirings M2.

On the other hand, when the TEG block 3 is rotated 90 degrees to the left to be arranged in the horizontal direction (in landscape) as shown in FIG. 15C, the column wirings M1 and M3 are in the horizontal direction and the row wirings M2 and M4 are in the vertical direction in the TEG 4G as shown in FIG. 15D.

Here, it is desirable that the gate of the transistor is arranged in the vertical direction also in the case where the TEG block 3 is rotated 90 degrees to the left. The reason is as follows. There is variation in size of a gate length due to lithography as factors of variation in characteristics of transistors. That is, it is known that the difference occurs in size variation of the gate length according to the arrangement direction of gate electrodes of transistors. Accordingly, characteristic difference occurs according to the difference in size variation of the gate length regardless of the arrangement direction of the TEG block 3 if the arrangement directions of transistors are not aligned.

Accordingly, when the TEG block is rotated 90 degrees to the left, the device to be measured 11 is connected to the unit array wiring 22 in the TEG 4G as shown in FIG. 15D. That is, the source and the drain of the device to be measured 11 are connected to the row wirings M4 and the gate and the back gate of the device to be measured 11 are connected to the column wirings M3.

According to the above structure, the arrangement direction of the device to be measured 11 can be changed without changing the column wirings M1, M3 and the row wirings M2, M4 to thereby eliminate the difference in size variation according to the arrangement directions of devices to be measured. Therefore, it is possible to reduce time for modifying the circuit for changing the arrangement direction of the device to be measured 11 so as to correspond to the rotation of the TEG block 3.

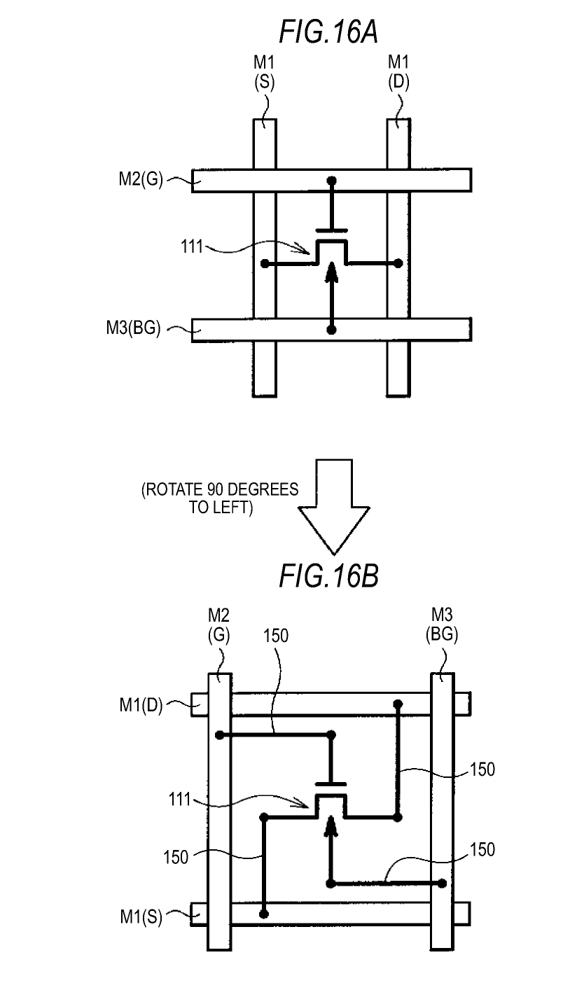

On the other hand, in related-art techniques, an additional wiring 150 is necessary for aligning the arrangement directions of a transistor 111 even when the TEG block is rotated 90 degrees to the left as shown in FIGS. 16A and 16B. Not only it takes a great deal of time to modify the circuit such as the re-wiring as described above but also excess wiring resistance is generated due to the additional wiring 150.

The case where one device to be measured 11 can be arranged in a rotated manner has been explained as described above, however, the above explanation corresponds to a case where the TEG 4G has plural device to be measured. In that case, it is possible to provide two unit array wirings with respect to each of plural devices to be measured and to connect each device to be measured to any of the unit array wiring according to the arrangement direction of the TEG block 3. Also in such case, respective unit array wirings are arranged so as to partially overlap each other in the same manner as the first embodiment, thereby providing many devices to be measured in the same area as long as wiring density permits. Therefore, it is possible to change the arrangement direction of the devices to be measured while arranging plural devices to be measured in high density and to flexibly respond to the change of the arrangement direction of the TEG block.

In order to change the arrangement direction of the device to be measured 11 alone without changing the arrangement of the column wirings M1, M3 and the row wirings M2, M4, it is preferable that wirings in the column wrings M1, M3 and the row wirings M2, M4 to be connected to the same portions of the device to be measured 11 and the device to be measured 11 arranged in a different direction are connected in common to a measurement pad. That is, one of the column wirings M1 and one of the row wirings M4 are connected to the source pad 30S. The other of the column wiring M1 and the other of the row wiring M4 are connected to the drain pad 30D. One of the row wiring M2 and one of the column wiring M3 are connected to the gate pad 30G. The other of the column wiring M2 and the other of the row wiring M2 are connected to the back gate pad 30H. Though the source pad 30S, the drain pad 30D, the gate pad 30G and the back gate pad 30H are omitted in the FIG. 15D, (S) is given to wirings connected to the source pad 30S, (D) is given to wirings connected to the drain pad 30D, (G) is given to the wirings connected to the gate pad 30G and (BG) is given to wirings connected to the back gate pad 30H.

As described above, the unit array wiring 21 including the column wirings M1 and the row wirings M2 provided in different layers and the unit array wiring 22 including the column wirings M3 and the row wirings M4 provided in different layers are provided in different layers, and the device to be measured 11 is connected to any one of plural unit array wirings 21 and 22, therefore, arrangement density of the devices to be measured 11 and 12 can be increased.

Particularly, in recent semiconductor integrated circuits, a technique of applying stress to a channel region to improve carrier mobility by arranging a stress film material close to transistors is used for the purpose of improving characteristics of the transistors. In the technique using the stress film material, effects due to the arrangement direction of the transistors are increased. The present embodiment is extremely suitable for characteristic evaluation of the transistors using such stress film material.

The modification examples 1-1 to 1-6 of the first embodiment can be also applied to the second embodiment.

### MODIFICATION EXAMPLE 2-1

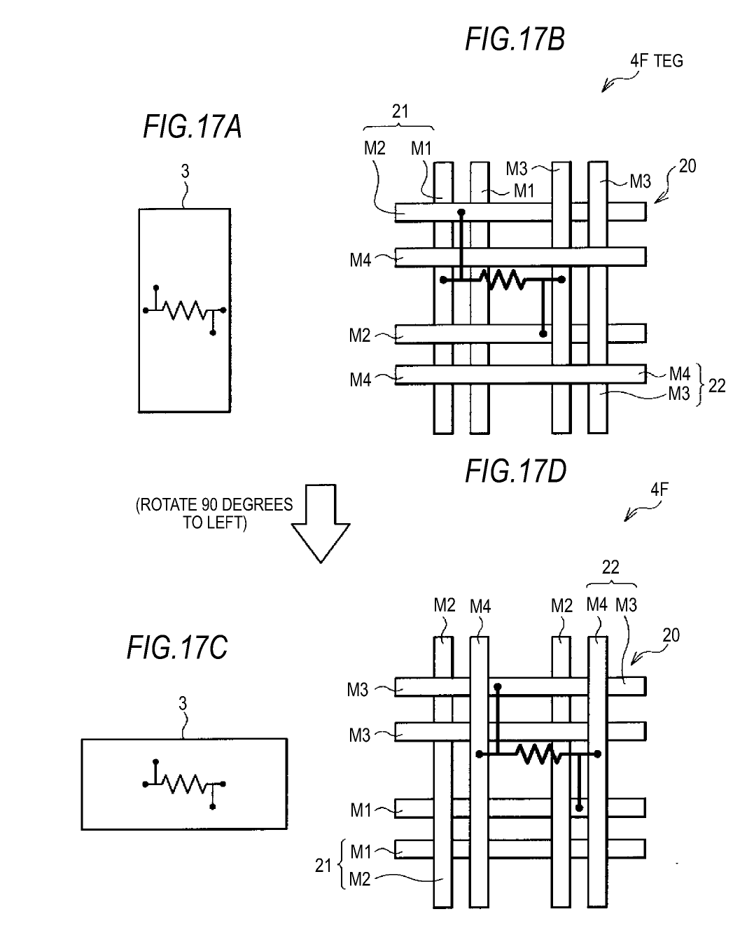

FIGS. 17A to 17C shows a configuration of a TEG 4F according to a modification example 2-1. The present modification example has the same configuration, operations and effects as the second embodiment except that the device to be measured is a resistor device.

The present technique has been explained by citing embodiments as the above, and the present technique is not limited to the above embodiments and various modifications are possible. For example, the case where two or three unit array wirings 21 to 23 are provided has been explained as examples in the above embodiments, however, the number of unit array wirings 21 to 23 may be four or more. Any wiring layers including the unit array wirings can be combined as long as different wiring layers are combined. For example, the case where the unit array wiring 21 includes the column wiring M1 and the row wiring M2 and the unit array wiring 22 includes the column wiring M3 and the row wiring M4 has been explained as the above, however, it is also preferable that the unit array wiring 21 includes the column wiring M1 and the row wiring M4 and the unit array wiring 22 includes the column wiring M3 and the row wiring M2. Similar modification can be applied to the second embodiment.

Furthermore, the case where the device to be measured is the transistor, the resistor device or the capacitor have been explained in the above embodiments, however, the present disclosure can be applied to cases where devices to be measured are other electronic components such as a diode.

Additionally, the case where the source and the drain of the device to be measured 11 are connected to the column wirings M1, the gate and the back gate of the device to be measured 11 are connected to the row wirings M2, the source and the drain of the device to be measured 12 are connected to the column wirings M3 and the gate and the back gate of the device to be measured 12 are connected to the row wirings M4 has been explained in the first embodiment. That is, the source and the drain of each of devices to be measured 11 and 12 are connected to the wiring layer in the same height in the z-direction and the gate and the back gate of each of devices to be measured 11 and 12 are connected to the wiring layer in the same height in the z-direction. However, the source and the drain of each of devices to be measured 11 and 12 can be connected to the wiring layers in different heights in the z-direction. Also, the gate and the back gate of each of the devices to be measured 11 and 12 can be connected to the wiring layers in different heights in the z-direction.

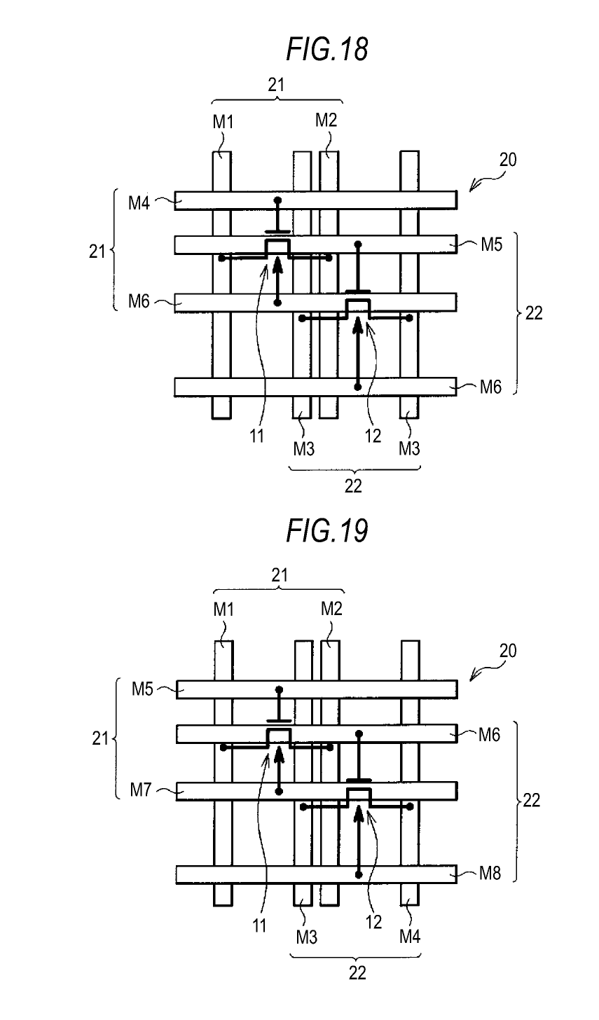

For example, as shown in FIG. 18, the unit array wiring 21 includes the column wirings M1 and M2 in the y-direction and the row wirings M4 and M6 in the x-direction, and the unit array wiring 22 includes two column wirings M3 and the row wirings M5 and M6 in the x-direction. The column wirings M1 and M2 are provided in different layers in the z-direction (for example, the first layer H1 and the second layer H2 from the side of the substrate 10) and the row wirings M4 and M6 are provided in different layers in the z-direction (for example, the fourth layer H4 and the sixth layer H6 from the side of the substrate 10). The row wirings M5 and M6 are provided in different layers in the z-direction (for example, the fifth layer H5 and the sixth layer H6 from the side of the substrate 10). The source of the device to be measured 11 is connected to the column wiring M1 and the drain thereof is connected to the column wiring M2, the gate thereof is connected to the row wiring M4 and the back gate thereof is connected to the row wiring M6. The source and the drain of the device to be measured 12 are connected to two column wirings M3, the gate thereof is connected to the row wiring M5 and the back gate thereof is connected to the row wiring M6. In this case, it is necessary that the column wirings M1 to M3 are provided in layers at different heights from the row wirings M4 to M6. That is, it is difficult to use the wiring layer at the same height between the column wirings M1 to M3 and the row wirings M4 to M6.

For example, as shown in FIG. 19, the unit array wiring 21 includes the column wirings M1 and M2 in the y-direction and the row wirings M5 and M7 in the x-direction, and the unit array wiring 22 includes the column wrings M3 and M4 in the y-direction and the row wirings M6 and M8 in the x-direction. The column wirings M1 and M2 are provided in different layers in the z-direction (for example, the first layer H1 and the second layer H2 from the side of the substrate 10), and the row wirings H5 and H7 are provided in different layers in the z-direction (for example, the fifth layer H5 and the seventh layer H7 from the side of the substrate 10). The column wirings M3 and M4 are provided in different layers in the z-direction (for example, the third layer H3 and the fourth layer H4 from the side of the substrate 10) and the row wirings M6 and M8 are provided in different layers in the z-direction (for example, the sixth layer H6 and the eight layer H8 from the side of the substrate 10). The source of the device to be measured 11 is connected to the column wiring M1, the drain thereof is connected to the column wiring M2, the gate thereof is connected to the row wiring M5 and the back gate thereof is connected to the row wiring M7. The source of the device to be measured 12 is connected to the column wiring M3, the drain thereof is connected to the column wiring M4, the gate thereof is connected to the row wiring M6 and the back gate thereof is connected to the row wiring M8. In this case, it is necessary that the column wirings M1 to M4 are provided in layers at different heights from the row wirings M5 to M8. That is, it is difficult to use the wiring layer at the same height between the column wirings M1 to M4 and the row wirings M5 to M8.

The combination of wiring layers shown in FIG. 18 and FIG. 19 can be changed in the cases where three or more unit array wirings are provided as in the second embodiment.

The present disclosure can be implemented as the following configuration.
(1) A semiconductor device including

plural devices to be measured,

a combined array wiring including plural unit array wirings each having a column wiring and a row wiring provided in different layers as well as each connected to any one of the plural devices to be measured, in which the plural unit array wirings are provided in layers different from each other.
(2) The semiconductor device described in the above (1),

in which the column wirings as well as the row wirings are provided at positions displaced to each other in a plane including a row direction and a column direction.
(3) The semiconductor device described in the above (2), further including a connection portion connecting the device to be measured and the unit array wiring, in which the connection portion is provided so as to avoid an intersection position between the column wiring and the row wiring in the plane.
(4) The semiconductor device described in the above (3),

in which the unit array wiring includes two column wirings in the same layer and two row wirings in the same layer.
(5) The semiconductor device described in the above (3),

in which the unit array wiring includes two column wirings in different layers and two row wirings in layers different from the layers of the column wirings.
(6) The semiconductor device described in the above (1),

in which wirings in the column wirings and the row wirings to be connected to the same portions of the plural devices to be measured are connected in common to a measurement pad.
(7) The semiconductor device described in the above (1),

in which the plural devices to be measured are arranged in the same orientation.
(8) The semiconductor device described in the above (1),

in which at least one of the plural devices to be measured is arranged in an orientation different from another device to be measured.
(9) The semiconductor device described in the above (1),

in which at least one of the plural devices to be measured can measure characteristics different from another device to be measured.
(10) A semiconductor device including

a combined array wiring including plural unit array wirings each having a column wiring and a row wiring provided in different layers, in which the plural unit array wirings are provided in layers different from each other, and

a device to be measured connected to anyone of the plural unit array wirings.
(11) The semiconductor device described in the above (10),

in which the column wirings as well as the row wirings are provided at positions displaced to each other in a plane including a row direction and a column direction.
(12) The semiconductor device described in the above (11),

further including a connection portion connecting the device to be measured and the unit array wiring, in which the connection portion is provided so as to avoid an intersection position between the column wiring and the row wiring in the plane.
(13) The semiconductor device described in the above (12),

in which the unit array wiring includes two column wirings in the same layer and two row wirings in the same layer.
(14) The semiconductor device described in the above (12),

in which the unit array wiring includes two column wirings in different layers and two row wirings in layers different from the layers of the column wirings.
(15) The semiconductor device described in the above (10),

in which wirings in the column wirings and the row wirings to be connected to the same portions of the device to be measured and the device to be measured arranged in a different direction are connected in common to a measurement pad.
(16) The semiconductor device described in the above (10),

in which plural devices to be measured are included, and the combined array wiring includes two unit array wirings with respect to each of the plural devices to be measured.

The present disclosure contains subject matter related to that disclosed in Japanese Priority Patent Application JP 2011-024568 filed in the Japan Patent Office on Feb. 8, 2011, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A semiconductor device comprising:
plural devices to be measured; and
a combined array wiring including plural unit array wirings each having a column wiring and a row wiring provided in different layers as well as each connected to any one of the plural devices to be measured, in which the plural unit array wirings are provided in layers different from each other.

2. The semiconductor device according to claim 1,
wherein the column wirings as well as the row wirings are provided at positions displaced to each other in a plane including a row direction and a column direction.

3. The semiconductor device according to claim 2, further comprising:
a connection portion connecting the device to be measured and the unit array wiring,
wherein the connection portion is provided so as to avoid an intersection position between the column wiring and the row wiring in the plane.

4. The semiconductor device according to claim 3,
wherein the unit array wiring includes two column wirings in the same layer and two row wirings in the same layer.

5. The semiconductor device according to claim 3,
wherein the unit array wiring includes two column wirings in different layers and two row wirings in layers different from the layers of the column wirings.

6. The semiconductor device according to claim 1,
wherein wirings in the column wirings and the row wirings to be connected to the same portions of the plural devices to be measured are connected in common to a measurement pad.

7. The semiconductor device according to claim 1,
wherein the plural devices to be measured are arranged in the same orientation.

8. The semiconductor device according to claim 1,
wherein at least one of the plural devices to be measured is arranged in an orientation different from another device to be measured.

9. The semiconductor device according to claim 1,
wherein at least one of the plural devices to be measured can measure characteristics different from another device to be measured.

10. A semiconductor device comprising:
a combined array wiring including plural unit array wirings each having a column wiring and a row wiring provided in different layers, in which the plural unit array wirings are provided in layers different from each other; and
a device to be measured connected to any one of the plural unit array wirings.

11. The semiconductor device according to claim 10,
wherein the column wirings as well as the row wirings are provided at positions displaced to each other in a plane including a row direction and a column direction.

12. The semiconductor device according to claim 11,
further including a connection portion connecting the device to be measured and the unit array wiring,
wherein the connection portion is provided so as to avoid an intersection position between the column wiring and the row wiring in the plane.

13. The semiconductor device according to claim 12,
wherein the unit array wiring includes two column wirings in the same layer and two row wirings in the same layer.

14. The semiconductor device according to claim 12,
wherein the unit array wiring includes two column wirings in different layers and two row wirings in layers different from the layers of the column wirings.

15. The semiconductor device according to claim 10,
wherein wirings in the column wirings and the row wirings to be connected to the same portions of the device to be measured and the device to be measured arranged in a different direction are connected in common to a measurement pad.

16. The semiconductor device according to claim 10,
wherein plural devices to be measured are included, and
the combined array wiring includes two unit array wirings with respect to each of the plural devices to be measured.
